(19) United States
(12) Patent Application Publication
(10) Pub. No.: US 2006/0066928 A1
(43) Pub. Date: Mar. 30, 2006

(54) Image processing apparatus and program

(75) Inventor: Yousuke Katou, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: FUJI PHOTO FILM CO., LTD.

(21) Appl. No.: 11/239,222

(22) Filed: Sep. 30, 2005

(30) Foreign Application Priority Data
Sep. 30, 2004 (JP) 2004-286210

(51) Int. Cl. G03F 3/08

(52) U.S. Cl. 358/518

(57) ABSTRACT

An image processing apparatus that performs image processing of an optically photographed image, comprises an image processing unit, a display and an adjustment input unit. The image processing unit performs color adjustment including white balance correction on the photographed image. The image processed by the image processing unit as a visible image is displayed. The adjustment input unit is provided with a color temperature adjustment key for adjusting a color tint of the image processed by the image processing unit using a color temperature as a variable, where the color adjustment performed by using the color temperature adjustment key at the image processing unit comprises color adjustment that concurrently adjusts at least two of three primary colors of the image.

### BACKGROUND OF THE INVENTION

The present invention relates to an image processing in which an optically photographed image (image data thereof) is processed, and more specifically to an image processing apparatus and a program with which it becomes possible even for an operator not having a sophisticated skill to perform color adjustment without losing color balance.

Conventionally, in exposure systems of a silver salt photographic technique, printing has been generally performed through analog exposure (areal exposure, direct exposure). That is, in such a system, exposure has been performed by placing a negative film having been developed at a predetermined printing position, irradiating light from a white light source (such as a halogen lamp), and imaging a transmission image from a negative film on printing paper.

Meanwhile, in recent years, printing apparatuses utilizing digital exposure, that is, digital photoprinters have been put into practical use. The digital photoprinters each obtain prints by photoelectrically reading images recorded on a photographic film such as a negative film or a color reversal film, converting the read images into digital signals, generating image data for recording by performing various kinds of image processing on the digital signals, and recording images (latent images) by scan-exposing a photosensitive material using recording light modulated in accordance with the image data.

In such a digital photoprinter, images are dealt with as digital image data, so it is possible to perform image processing not only on images photographed on a film but also on images photographed with a digital camera (DSC) or the like and image data recorded as digital data on a magnetic recording medium, such as a CD-R, a flexible disk, or a removable hard disk (Zip, Jaz, or the like), or a recording medium, such as an MO disk (magneto-optical recording medium), and to output the images and image data as prints.

By the way, the photographing states of images photographed on a color negative film and images photographed with a digital camera are not necessarily uniform. That is, images are photographed under various conditions and are influenced by the conditions.

For instance, there are various photographing light conditions such as daylight, light from a fluorescent lamp, and light from an electronic flash. Therefore, there is a case where photographed images are influenced by the color components (spectral wavelength distributions) of their photographing light and images, whose color tints (color balance) are inappropriate, are outputted.

In order to solve such inconvenience, white balance correction (gray balance correction) is performed. As a method of the white balance correction, a method with which the large area transmission densities (LATDs) of color negative films are measured and average colors on prints are set close to gray by changing the light quality of print light sources in accordance with the magnitudes of RGB densities, a method with which the color temperatures of photographing light sources of images are estimated using color information on gray or flesh color of the images and the colors of the images are corrected in accordance with the estimated color temperatures so that the color tints of the images become appropriate (see JP 2003-209856 A), and the like are known.

Depending on photographing scenes, however, the white balance correction is not necessarily performed correctly.

Therefore, in ordinary cases, so-called inspection, in which finish prediction images (inspection images) are displayed on a display of a photoprinter and confirmation of the images is performed, is conducted and when the color tints of any images are inappropriate, color adjustment is performed on the images by an operator (inspection person).

Such color adjustment by an operator at a photoprinter is ordinarily carried out through amendment of images (image data) in specific colors by specific amounts corresponding to input using color adjustment keys such as a C (cyan) key, an M (magenta) key, and a Y (yellow) key.

For an experienced operator having a sophisticated skill, it is possible to obtain finished images having optimum color tints with ease by appropriately adjusting multiple colors individually using the color adjustment keys set for the respective colors.

For an operator not having a sufficient skill, however, it is impossible to sufficiently grasp image color tint changes resulting from input using the color adjustment keys. Therefore, it is extremely difficult for such an operator to obtain finished images having optimum color tints by adjusting respective colors and there is also a case where the color balance of images is conversely lost as a result of the color adjustment.

### SUMMARY OF THE INVENTION

It is therefore an object of the present invention to solve the problems of the conventional techniques described above by providing an image processing apparatus and a program with which at a photoprinter, it becomes possible even for an operator not having a sufficient skill to appropriately perform color adjustment (color balance adjustment) on an image through simple manipulation and to output a high-quality image having an appropriate color tint with stability.

In order to attain the object described above, the present invention provides an image processing apparatus that performs image processing of an optically photographed image, comprising: an image processing unit that performs color adjustment including white balance correction on the photographed image; a display that displays the image processed by the image processing unit as a visible image; and an adjustment input unit provided with a color temperature adjustment key for adjusting a color tint of the image processed by the image processing unit using a color temperature as a variable, wherein the color adjustment performed by using the color temperature adjustment key at the image processing unit comprises color adjustment that concurrently adjusts at least two of three primary colors of the image.

Preferably, the image processing unit estimates a color temperature of a light source upon photographing the image and performs the white balance correction on the image based on the estimated color temperature.

Also preferably, the color adjustment performed by using the color temperature adjustment key at the image processing unit comprises color adjustment that is performed so that gray chromaticity changes along a black body locus obtained by connecting chromaticity points on a chromaticity coordinate system of black body radiation light at an absolute temperature.

At that time, more preferably, the image processing unit estimates a color temperature of a light source upon photographing the image and performs the white balance correction on the image based on the estimated color temperature, the adjustment input unit sets a color temperature difference from the estimated color temperature through input using the color temperature adjustment key, and the image processing unit obtains correction amount differences for at least two of the three primary colors based on the black body locus from the set color temperature difference and performs the color adjustment on the image having undergone the white balance correction using the correction amount differences. Two of the three primary colors may be cyan and yellow.

The present invention also provides a computer-executable program with which an optically photographed image is acquired and is subjected to image processing by a computer. The program comprises: a procedure for causing a computation unit of the computer to perform white balance correction on image data of the optically photographed image; a procedure for causing a display to display the image having undergone the white balance correction; a procedure for causing the computation unit to calculate a correction amount for color adjustment in accordance with image color tint adjustment input, in which a color temperature is used as a variable, performed based on the image displayed on the display; and a procedure for causing the computation unit to perform the color adjustment on at least two of three primary colors of the image data subjected to the white balance correction using the calculated correction amount.

Preferably, the white balance correction comprises color correction in which a color temperature of a photographing light source of the image is estimated and correction is performed based on the estimated color temperature.

Also preferably, the correction amount for the color adjustment is calculated so that gray chromaticity changes along a black body locus obtained by connecting chromaticity points on a chromaticity coordinate system of black body radiation light at an absolute temperature. More preferably, the white balance correction on the image comprises correction that is performed based on a result of estimation of a color temperature of a photographing light source of the image, a color temperature difference from the result of the estimation of the color temperature is set through the image color tint adjustment input, and the computation unit is caused to obtain correction amount differences for at least two of the three primary colors based on the black body locus from the set color temperature difference and perform the color adjustment on the image subjected to the white balance correction using the correction amount differences. At that time, two of the three primary colors may be cyan and yellow.

According to the present invention, the necessity in the conventional color adjustment to deal with multiple color adjustment keys is eliminated and it becomes possible to perform color adjustment on an image while maintaining white balance through concurrent changing of multiple colors using one key that is a color temperature adjustment key. Therefore, even for an operator not having a sufficient skill, it becomes possible to perform appropriate color adjustment on an image through simple, sensuous, and easy-to-understand manipulation, such as a color temperature increase/a color temperature decrease manipulation like a density increase (addition)/a density decrease (subtraction) manipulation based on density adjustment, and to output a high-quality image having a favorable color tint (color balance) with stability.

### BRIEF DESCRIPTION OF THE DRAWINGS

FIG. 1 is a block diagram conceptually showing an example of the image processing apparatus according to the present invention; and

FIG. 2 is a flowchart for explanation of an operation of the image processing apparatus shown in FIG. 1.

### DETAILED DESCRIPTION OF THE PREFERRED EMBODIMENTS

Hereinafter, the image processing apparatus and the program according to the present invention will be described in detail based on a preferred embodiment illustrated in the accompanying drawings.

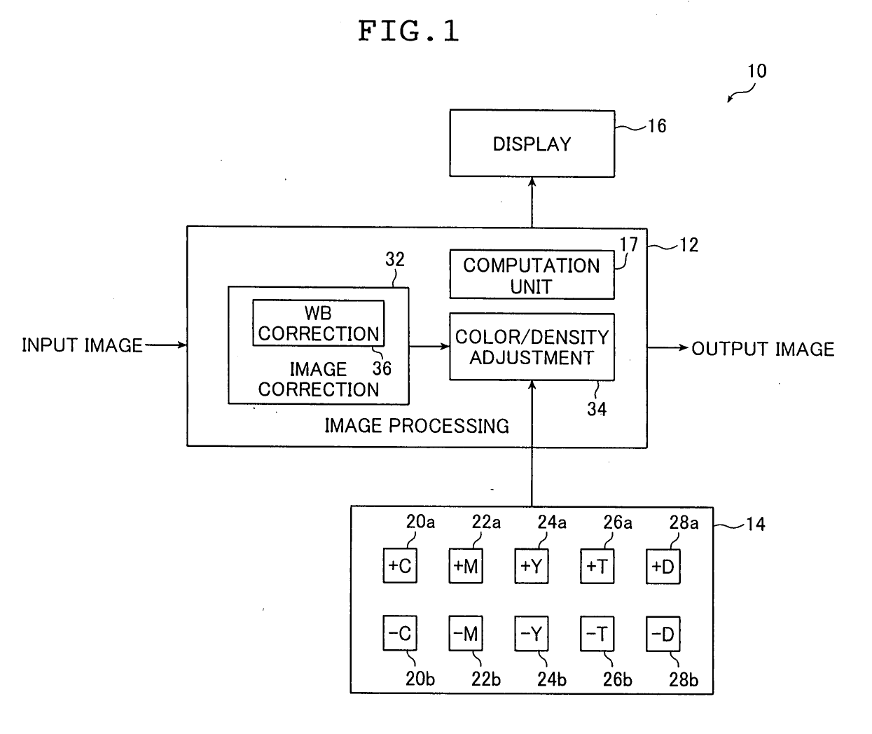

FIG. 1 is a block diagram showing the outline of an example of the image processing apparatus according to the present invention.

An image processing apparatus 10 shown in FIG. 1 is an apparatus that obtains an image for output (output image (output image data)) by performing necessary image processing on an input image (input image data), and includes an image processing unit 12, a color/density adjustment keyboard 14, and a display 16. The image processing apparatus 10 constitutes an image processing apparatus (image processor) of the aforementioned digital photoprinter (digital mini-lab machine), for instance. A computer may be used in the image processing unit 12. In this case, various kinds of computation of image processing carried out at the image processing unit 12 is performed by a computation unit 170 on the computer.

Each input image into the image processing apparatus 10 according to the present invention is not specifically limited and may be an image obtained by photoelectrically reading an image photographed on a negative/positive photographic film or may be an image photographed with a digital camera, for instance.

The color/density adjustment keyboard 14 is a keyboard for inputting designation of image color and density adjustment. In the illustrated example, the color/density adjustment keyboard 14 includes four kinds of color adjustment keys that are cyan (C) adjustment keys 20 (+C key 20a and −C key 20b), magenta (M) adjustment keys 22 (+M key 22a and −M key 22b), yellow (Y) adjustment keys 24 (+Y key 24a and −Y key 24b), and color temperature (T) adjustment keys 26 (+T key 26a and −T key 26b), and density (D) adjustment keys 28 (+D key 28a and −D key 28b).

Except for having the color temperature adjustment keys 26 (+T key 26a and −T key 26b) that are a feature of the present invention, the color/density adjustment keyboard 14 is basically the same as known color/density adjustment keyboards of various photoprinters (mini-lab machines).

In the illustrated example, as a preferable form, the adjustment keys for respective colors of C, M, and Y are provided in addition to the color temperature adjustment keys 26, but the present invention is not limited to this and a form may be used instead which includes only the color temperature adjustment keys 26 or includes only the color temperature adjustment keys 26 and the density adjustment keys.

The display 16 is a known display and performs displaying of each image processed by the image processing unit 12 (so-called inspection image in the case of a mini-lab machine), displaying for various kinds of manipulation through a graphical user interface (GUI), and the like.

The image processing apparatus 10 in the illustrated example has the color/density adjustment keyboard 14 for performing color/density adjustment. However, the present invention is not limited to this and a color and density adjustment input unit may be constructed instead using a GUI which displays the cyan adjustment keys 20, the magenta adjustment keys 22, the yellow adjustment keys 24, the color temperature adjustment keys 26, the density adjustment keys 28, and the like on the display 16. Also, in this case, the color and density adjustment input unit may be composed of slider bars instead of the keys (buttons).

In the present invention, the adjustment input unit may include both of the keyboard and the GUI or may include only one of them.

The image processing unit 12 is a unit that obtains each output image by performing necessary image processing on each input image and further performing color/density adjustment on the image in accordance with color/density adjustment designation performed using the color/density adjustment keyboard 14, and that includes an image correction unit 32 and a color/density adjustment unit 34. Also, the image correction unit 32 includes a white balance (WB) correction unit 36.

Also, the image processing unit 12 may perform data processing, such as log conversion, negative/positive conversion, offset correction, dark correction, and shading correction, on the input image as necessary.

The image correction unit 32 performs necessary image correction including WB correction by the WB correction unit 36 on the input image.

No specific limitation is imposed on the image correction (image processing) by the image correction unit 32 and it is possible to perform various kinds of image correction. As examples of the image correction, it is possible to cite image enlargement/reduction (electronic scaling processing), gradation correction, density correction, color saturation correction, sharpness processing, dodging processing (image (density) dynamic range compression/expansion), color space conversion processing, red eye correction, dust/flaw removal processing, and the like. Also, it is sufficient that the image correction described above is carried out with known methods.

The WB correction (gray balance correction) is color correction that corrects image color balance.

As described above, photographing in image photographing onto a photographic film and image photographing with a digital camera is performed under various light conditions such as average daylight, daylight under a clear sky or a cloudy sky, light from a fluorescent lamp, or light from an electronic flash.

The wavelength component of light varies depending on the kind of its light source. Therefore, the color tint (wavelength component) of light irradiated varies from photographing light source to photographing light source. In the case of certain light sources, such color tints are reflected in images and images photographed become inappropriate in color tint (color balance).

The WB correction is performed in order to eliminate such inappropriateness, in which image color balance is adjusted so that gray or white in an image becomes, for instance, an appropriate achromatic color.

No specific limitation is imposed on a method of the WB correction and it is possible to use a known method such as a method, with which a large-area density of an image is measured and the color tint of the image is corrected so that an average color on the image gets close to gray, like a method that uses a so-called large area transmission density (LATD).

In the illustrated example, as a preferable form, the WB correction unit 36 performs the WB correction by estimating the color temperature of a photographing light source using color information on gray and/or flesh color in an image, obtaining a correction condition for converting the estimated color temperature into a white reference color temperature (5500 K, for instance), and correcting the image under the condition. More specifically, the WB correction is performed by estimating the color temperature of the photographing light source, setting a correction condition under which the gray chromaticity (chromaticity coordinates (r, b);r=R/(R+G+B),b=B/(R+G+B)) of the estimated color temperature of photographing light source coincides with the gray chromaticity of the white reference color temperature, and correcting the image under the correction condition. The white balance correction method is described in detail in JP 2003-209866 A cited above.

The color/density adjustment unit 34 is a unit that adjusts the color/density of the image corrected by the image correction unit 32 in accordance with adjustment input with the keys of the color/density adjustment keyboard 14.

That is, for instance, when the +C key 20a is pushed, the color/density adjustment unit 34 adjusts the image so that the C density of the image is increased in accordance with the number of times of the key pushed. Also, when the −Y key 24b is pushed, the color/density adjustment unit 34 adjusts the image so that the Y density of the image is decreased in accordance with the number of times of the key pushed. Further, when the +D key 28a is pushed, the color/density adjustment unit 34 increases the density of the image in accordance with the number of times of the key pushed. Still further, when the −D key 28b is pushed, the color/density adjustment unit 34 decreases the density of the image in accordance with the number of times of the key pushed.

It is sufficient that the image color/density adjustment corresponding to input with the cyan adjustment keys 20, the magenta adjustment keys 22, the yellow adjustment keys 24, and the density adjustment keys 28 is carried out with a known method such as a method that is implemented in an ordinary digital photoprinter or the like.

In contrast to this, when color adjustment is designated using the color temperature adjustment keys 26 (+T key 26a and −T key 26b) (this color adjustment will be hereinafter referred to as the “color temperature adjustment”), the color/density adjustment unit 34 performs color adjustment on the image by carrying out color adjustment of the C density and Y density of the image while maintaining the white balance of the image.

In the illustrated example, the color temperature adjustment adjusts the color of the image with reference to the color temperature of the photographing light source estimated by the WB correction unit 36 in the WB correction in accordance with the number of times of the color temperature adjustment keys 26 pushed so that the adjustment becomes the same as the WB correction at the time of the changing of the estimated color temperature by the WB correction unit 36.

That is, when the color temperature adjustment key is pushed by the operator for the sake of image color adjustment, a difference from the estimated color temperature is set in accordance with the number of times of key push, correction amount differences with respect to the C density and the Y density to be described later are obtained from the estimated color temperature and the difference so that gray chromaticity changes along a black body locus on a gray chromaticity coordinate system, and color adjustment is performed in accordance with the correction amount differences.

It should be noted here that the black body locus refers to a locus curved line obtained by connecting chromaticity points on a gray chromaticity coordinate system of black body radiation light at an absolute temperature.

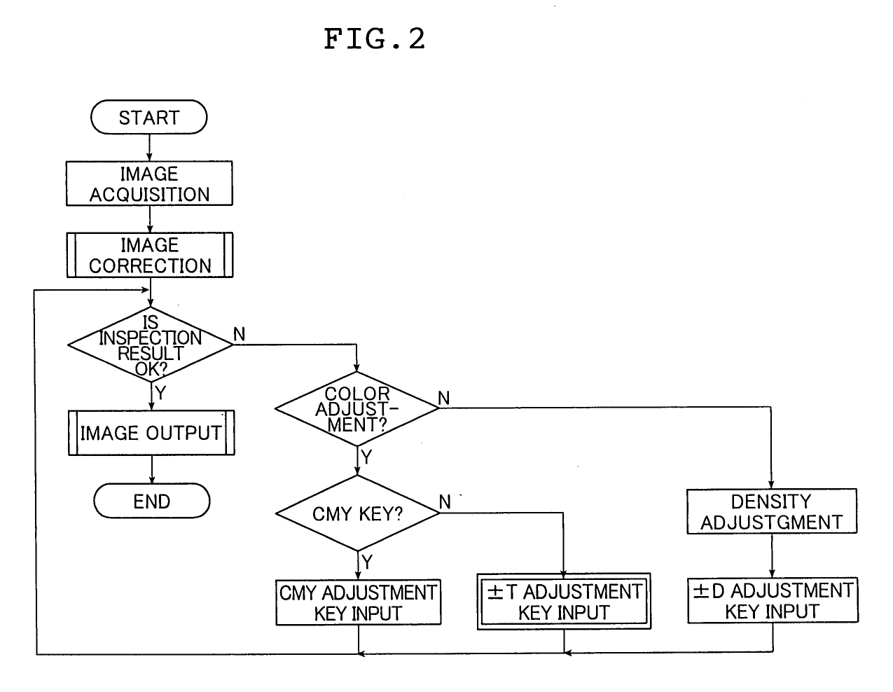

Hereinafter, the color temperature adjustment using the color temperature adjustment keys 26 and the present invention will be described in more detail by explaining an operation of the image processing apparatus 10 with reference to a flowchart in FIG. 2.

Here, the program according to the present invention is a program for causing a computer to carry out the following operations. Note that with the program according to the present invention, an adjustment input unit is set in place of the color/density adjustment keyboard 14 by displaying of each color/color temperature/density adjustment key through the displaying on the display described above, performing allocation of each color/color temperature/density adjustment key to a keyboard of the computer, and the like.

First, when an image is acquired, predetermined image correction is performed on the image at the image correction unit 32 in the manner described above. In the image correction, the WB correction by the WB correction unit 36 is also contained. That is, the WB correction is performed in which the photographing light source of the image is estimated and the color of the image is corrected so that the gray chromaticity of the color temperature of the photographing light source coincides with the gray chromaticity of the white reference color temperature (5500 K).

Examples of the gray chromaticity and the WB correction amount at each color temperature are shown in Table 1 given below.

TABLE 1

| | | | | | Correction | |
|---|---|---|---|---|---|---|
| Color | Gray | | WB Correction | | Amount | |
| Temperature | Chromaticity | | Amount | | Difference | |
| [K] | r | b | C | Y | C | Y |
| 3,000 | 0.57 | 0.12 | 8.3 | −14.7 | | |
| | | | | | 4.5 | 8.4 |
| 4,000 | 0.44 | 0.22 | 3.8 | −6.2 | | |
| | | | | | 2.8 | 4.6 |
| 5,000 | 0.36 | 0.30 | 1.0 | −1.6 | | |
| | | | | | 1.0 | 1.6 |
| 5500 | 0.33 | 0.33 | 0 | 0 | | |
| | | | | | 0.8 | 1.3 |
| 6,000 | 0.31 | 0.36 | −0.8 | 1.3 | | |
| | | | | | 1.3 | 2.1 |
| 7,000 | 0.28 | 0.40 | −2.1 | 3.4 | | |
| | | | | | 0.9 | 1.5 |
| 8,000 | 0.25 | 0.44 | −3.0 | 4.9 | | |
| | | | | | 0.7 | 1.2 |
| 9,000 | 0.24 | 0.46 | −3.7 | 6.1 | | |
| | | | | | 0.5 | 0.9 |
| 10,000 | 0.22 | 0.48 | −4.2 | 7.0 | | |

In this example, for instance, when the color temperature of the photographing light source is estimated at 4,000 K, the WB correction unit 36 performs the WB correction by correcting the color of the image through increase of C by 3.8 and decrease of Y by 6.2 so that the gray chromaticity (0.44, 0.22) at 4,000 K coincides with the gray chromaticity (0.33, 0.33) at 5500 K that is a reference.

Also, when the color temperature of the photographing light source is estimated at 8,000 K, the WB correction unit 36 performs the WB correction by correcting the color of the image through decrease of C by 3.0 and increase of Y by 4.9 so that the gray chromaticity (0.25, 0.44) at 8,000 K coincides with the gray chromaticity (0.33, 0.33) at 5500 K that is the reference.

It should be noted here that the WB correction amounts with respect to C and Y are respectively correction amounts corresponding to the numbers of times of the cyan adjustment keys 20 and the yellow adjustment keys 24 pushed. That is, the image color correction described above, in which “C is increased by 3.8 and Y is decreased by 6.2”, corresponds to adjustment amounts at the time when color adjustment is performed by pushing the +C key 20a 3.8 times and pushing −Y key 24b 6.2 times. For example, in a setting in which a density value changes by 0.03 each time the color adjustment key is pushed, the correction, in which “C is increased by 3.8 and Y is decreased by 6.2”, means image color correction, in which C is increased by 0.114 and Y is decreased by 0.186 on the density value basis, from “3.8×0.03=0.114, −6.2×0.03=−0.186”.

When the image correction by the image correction unit 36 is ended, the image having been corrected is displayed on the display 16 and confirmation (inspection) of the image by the operator is conducted.

When the image is appropriate (inspection result is OK), output designation is issued, an output image is outputted, and the image processing is ended.

On the other hand, when the image is inappropriate, the color/density of the image is adjusted using the color/density adjustment keyboard 14.

In the case of density adjustment, the density adjustment key 28 is pushed as described above. In accordance with the key pushed, the color/density adjustment unit 34 increases or decreases the density of the image in the manner described above.

Also, when the cyan adjustment key 20, the magenta adjustment key 22, and the yellow adjustment key 24 are pushed in color adjustment, the color/density adjustment unit 34 increases or decreases the C density of the image, increases or decreases the M density, and increases or decreases the Y density in accordance with the color adjustment keys pushed in the manner described above.

In contrast to this, when the color temperature adjustment key 26 is pushed, the color/density adjustment unit 34 performs color temperature adjustment while maintaining the white balance of the image by adjusting the C density and the Y density of the image in a manner described below.

It should be noted here that in order to simplify the construction and facilitate understanding, the following example will be explained by assuming that the WB correction and the color temperature adjustment are performed in increments of 1,000 K (500 K in a range from 5,000 to 6,000 K) of the color temperature, but the present invention is not limited to this as a matter of course.

Also, in the illustrated example, one push of the color temperature adjustment key of the apparatus corresponds to an increment of 1,000 K in a color temperature range from 3,000 to 5,000 K and in a color temperature range from 6,000 to 10,000 K and corresponds to an increment of 500 K in a color temperature range from 5,000 to 6,000 K, but the present invention is not limited to this as a matter of course.

As described above, the color temperature adjustment is performed with reference to the color temperature of the photographing light source estimated by the WB correction unit 36.

When the photographing light source of the image is estimated at 4,000 K by the WB correction unit 36, for instance, the WB correction unit 36 performs the WB correction in accordance with 4,000 K. When the operator inspects the image and judges that the image is red (that is, the estimated color temperature is lower and the WB correction is not enough), the operator pushes the +T key 26a of the color temperature adjustment keys 26 once in order to set the color temperature higher. This input designation performed at the image processing apparatus 10 means designation of changing of the estimated color temperature of the photographing light source to 5,000 K through increase from 4,000 K by 1000 K.

As described above, when the color temperature of the photographing light source is estimated at 4,000 K, the WB correction unit 36 performs the WB correction by correcting the color of the image so that C is increased by 3.8 and Y is decreased by 6.2. On the other hand, as shown in Table 1 described above, when the color temperature of the photographing light source is estimated at 5,000 K, the WB correction unit 36 performs the WB correction by correcting the color of the image so that C is increased by 1.0 and Y is decreased by 1.6 with the +T key 26a pushed once.

As shown in Table 1, correction amount differences therebetween with respect to C and Y are respectively 2.8 and 4.6. Accordingly, by correcting C and Y by the differences, it becomes possible to obtain the same image as in the case of the WB correction at the time when the color temperature of the photographing light source is estimated at 5,000 K.

Accordingly, the color/density adjustment unit 34 adjusts the color of the image so that C is decreased by 2.8 and Y is increased by 4.6.

When the operator further pushes the +T key 26a once afterward, the color temperature of the photographing light source is set at 5500 K, though the color temperature of the photographing light source estimated at 4,000 K in the WB correction is further increased up to 5,000 K at the time of the adjustment.

As shown in Table 1, the WB correction amount differences between 5,000 K and 5500 K with respect to C and Y are respectively 1.0 and 1.6. Accordingly, the color/density adjustment unit 34 adjusts the color of the image so that C is further decreased by 1.0 and Y is further increased by 1.6.

On the other hand, when the photographing light source of the image is estimated at 8,000 K by the WB correction unit 36, the WB correction unit 36 performs the WB correction in accordance with 8,000 K. When the operator inspects the image and judges that the image is blue (that is, the estimated color temperature is higher and the WB correction is not enough), the operator pushes the −T key 26b of the color temperature adjustment keys 26 once in order to set the color temperature lower. This input designation means designation of decrease of the color temperature of the photographing light source estimated in the WB correction to 7,000 K by 1,000 K.

As described above, when the color temperature of the photographing light source is estimated at 8,000 K, the WB correction unit 36 performs the WB correction by correcting the color of the image so that C is decreased by 3.0 and Y is increased by 4.9. Also, when the color temperature of the photographing light source is estimated at 7,000 K, as shown in Table 1, the WB correction unit 36 performs the WB correction by correcting the color of the image so that C is decreased by 2.1 and Y is increased by 3.4.

As shown in Table 1, the differences therebetween with respect to C and Y are respectively 0.9 and 1.5, so the color/density adjustment unit 34 adjusts the color of the image so that C is increased by 0.9 and Y is decreased by 1.5 in accordance with the −T key 26b pushed.

As described above, the WB correction at the apparatus in the illustrated example is performed by setting the gray chromaticity of the estimated color temperature of the photographing light source to agree with the gray chromaticity of a white reference light source.

Therefore, the image color adjustment is performed in a form in which the color temperature of the photographing light source estimated in the WB correction is corrected. Through the color temperature adjustment, the color of the image is adjusted so that the gray chromaticity of the image vary along the black body locus of gray, and it is possible to perform the image color adjustment under a state where white balance is maintained. That is, the gray chromaticity in Table 1 is determined so that it changes in accordance with the black body locus obtained by connecting chromaticity points on a chromaticity coordinate system of black body radiation light at an absolute temperature. Accordingly, when adjustment is performed with the color temperature adjustment key, gray in the image is positioned on a point of the black body locus.

When the image becomes appropriate as a result of the image adjustment described above (inspection result becomes OK), output designation is issued, an output image obtained as a result of the color/density adjustment is outputted, and the image processing is ended.

As is apparent from the above description, with the image processing apparatus (program) according to the present invention, the necessity to deal with multiple color adjustment keys is eliminated and it becomes possible to perform image color adjustment while maintaining image white balance by changing multiple colors with one key that is the color temperature adjustment keys 26. Therefore, it becomes possible to perform appropriate image color adjustment through sensuous and easy-to-understand manipulation such as simple color temperature increase/color temperature decrease manipulation, which makes it possible even for an operator not having a sufficient skill to output a high-quality image having a favorable color tint (color balance) with stability.

It should be noted here that the image processing apparatus according to the present invention may be constructed using a computer. In this case, the computer is caused to execute the following program.

That is, the program includes: a procedure for causing a computation unit of the computer to perform white balance correction on image data of the optically photographed image; a procedure for causing a display to display the image having undergone the white balance correction; a procedure for causing the computation unit of the computer to calculate a correction amount for color adjustment in accordance with image color tint adjustment input, using a color temperature as a variable, based on the image displayed by the display; and a procedure for causing the computation unit of the computer to perform the color adjustment on at least two of three primary colors of the image data having undergone the white balance correction using the calculated correction amount.

At this time, the white balance correction is color correction in which a color temperature of a photographing light source of the image is estimated and correction is performed based on the estimated color temperature. The correction amount for the color adjustment is calculated so that gray chromaticity changes in accordance with a black body locus obtained by connecting chromaticity points on a chromaticity coordinate system of black body radiation light at an absolute temperature.

Further, the color adjustment on the white balanced image is correction that is performed based on a result of estimation of a color temperature of a light source upon photographing the image, a color temperature difference for the color adjustment is set from the result of the estimation of the color temperature through the image color tint adjustment input, and the computation unit is caused to obtain correction amount differences for at least two of the three primary colors based on the black body locus described above from the set color temperature difference and perform the color adjustment on the image having undergone the white balance correction using the correction amount differences.

The image processing apparatus and program according to the present invention have been described in detail above, however, the present invention is not limited to the embodiment described above and it is of course possible to make various modifications and changes without departing from the gist of the present invention.

For instance, in the embodiment described above, image color adjustment corresponding to input with the color temperature adjustment key is achieved through C and Y adjustment, however, the present invention is not limited to this and it is sufficient that at least two of the three primary colors are adjusted. For instance, the image color adjustment may be performed while maintaining image white balance by adjusting three colors that are C, M, and Y. Note that M is used as the reference of color correction in many cases and when consideration is given to this point, it is preferable that the image color adjustment corresponding to the color temperature adjustment key be achieved through the C and Y adjustment.

Also, the embodiment described above is an example in which the present invention is applied to image processing of digital image data, however, the present invention is not limited to this and is also applicable to color adjustment at an analog photoprinter that performs printing onto printing paper with projection light from a film. In this case, it is sufficient that setting of insertion amounts of, for instance, a C filter and a Y filter corresponding to input designation with the color temperature adjustment key is performed instead of color adjustment by means of image data.

What is claimed is:

1. An image processing apparatus that performs image processing of an optically photographed image, comprising:
an image processing unit that performs color adjustment including white balance correction on the photographed image;
a display that displays the image processed by the image processing unit as a visible image; and
an adjustment input unit provided with a color temperature adjustment key for adjusting a color tint of the image processed by the image processing unit using a color temperature as a variable,
wherein the color adjustment performed by using the color temperature adjustment key at the image processing unit comprises color adjustment that concurrently adjusts at least two of three primary colors of the image.

2. The image processing apparatus according to claim 1,
wherein the image processing unit estimates a color temperature of a light source upon photographing the image and performs the white balance correction on the image based on the estimated color temperature.

3. The image processing apparatus according to claim 1,
wherein the color adjustment performed by using the color temperature adjustment key at the image processing unit comprises color adjustment that is performed so that gray chromaticity changes along a black body locus obtained by connecting chromaticity points on a chromaticity coordinate system of black body radiation light at an absolute temperature.

4. The image processing apparatus according to claim 3,
wherein the image processing unit estimates a color temperature of a light source upon photographing the image and performs the white balance correction on the image based on the estimated color temperature,
the adjustment input unit sets a color temperature difference from the estimated color temperature through input using the color temperature adjustment key, and
the image processing unit obtains correction amount differences for at least two of the three primary colors based on the black body locus from the set color temperature difference and performs the color adjustment on the image having undergone the white balance correction using the correction amount differences.

5. The image processing apparatus according to claim 1,
wherein two of the three primary colors are cyan and yellow.

6. A computer-executable program with which an optically photographed image is acquired and is subjected to image processing by a computer,
the program comprising:
a procedure for causing a computation unit of the computer to perform white balance correction on image data of the optically photographed image;
a procedure for causing a display to display the image having undergone the white balance correction;
a procedure for causing the computation unit to calculate a correction amount for color adjustment in accordance with image color tint adjustment input, in which a color temperature is used as a variable, performed based on the image displayed on the display; and
a procedure for causing the computation unit to perform the color adjustment on at least two of three primary colors of the image data subjected to the white balance correction using the calculated correction amount.

7. The program according to claim 6,
wherein the white balance correction comprises color correction in which a color temperature of a photographing light source of the image is estimated and correction is performed based on the estimated color temperature.

8. The program according to claim 6,
wherein the correction amount for the color adjustment is calculated so that gray chromaticity changes along a black body locus obtained by connecting chromaticity points on a chromaticity coordinate system of black body radiation light at an absolute temperature.

9. The program according to claim 8,
wherein the white balance correction on the image comprises correction that is performed based on a result of estimation of a color temperature of a photographing light source of the image,
a color temperature difference from the result of the estimation of the color temperature is set through the image color tint adjustment input, and
the computation unit is caused to obtain correction amount differences for at least two of the three primary colors based on the black body locus from the set color temperature difference and perform the color adjustment on the image subjected to the white balance correction using the correction amount differences.

10. The program according to claim 6,
wherein two of the three primary colors are cyan and yellow.
